(19) United States
(12) Patent Application Publication
(10) Pub. No.: US 2025/0019567 A1
(43) Pub. Date: Jan. 16, 2025

(54) CHEMICAL MECHANICAL POLISHING COMPOSITION AND METHOD FOR PREVENTING POLISHING PAD GROOVE CLOGGING

(71) Applicant: DuPont Electronic Materials Holding, Inc., Newark, DE (US)

(72) Inventors: Yi Guo, Newark, DE (US); David Mosley, Media, PA (US)

(21) Appl. No.: 18/351,031

(22) Filed: Jul. 12, 2023

(51) Int. Cl. C09G 1/02; B24B 37/04; C09K 3/14; H01L 21/3105

(52) U.S. Cl. CPC C09G 1/02; B24B 37/044; C09K 3/1409; H01L 21/31053

(57) ABSTRACT

An aqueous based chemical mechanical polishing composition for polishing a semiconductor substrate includes an abrasive having bimodal distributed colloidal silica particles which include elongated colloidal silica particles, polyvinyl alcohol 80% hydrolyzed to less than or equal to 90% hydrolyzed, an electrolyte and a pH greater than 7, and a method of polishing the semiconductor substrate to planarize the substrate. The aqueous based chemical mechanical polishing composition and method inhibits polishing pad groove clogging during chemical mechanical polishing of the semiconductor substrates.

### FIELD OF THE INVENTION

The present invention is directed to a chemical mechanical polishing composition and method for preventing polishing pad groove clogging during chemical mechanical polishing and planarization. More specifically, the present invention is directed to a chemical mechanical polishing composition and method for preventing polishing pad groove clogging during chemical mechanical polishing and planarization, wherein the chemical mechanical polishing composition includes water, an abrasive having bimodal distributed colloidal silica particles including elongated colloidal silica particles, polyvinyl alcohol 80% to less than or equal to 90% hydrolyzed, an electrolyte, a pH greater than 7 and good conductivity.

### BACKGROUND OF THE INVENTION

In the fabrication of integrated circuits and other electronic devices, multiple layers of conducting, semiconducting and dielectric materials are deposited on or removed from a surface of a semiconductor wafer. Thin layers of conducting, semiconducting, and dielectric materials can be deposited by various deposition techniques. Common deposition techniques in modern processing include physical vapor deposition (PVD), also known as sputtering, chemical vapor deposition (CVD), plasma-enhanced chemical vapor deposition (PECVD), and electrochemical plating (ECP).

As layers of materials are sequentially deposited and removed, the uppermost surface of the wafer becomes non-planar. Because subsequent semiconductor processing (e.g., metallization) requires the wafer to have a flat surface, the wafer needs to be planarized. Planarization is useful in removing undesired surface topography and surface defects, such as rough surfaces, agglomerated materials, crystal lattice damage, scratches, and contaminated layers or materials.

Chemical mechanical planarization, or chemical mechanical polishing (CMP), is a common technique used to planarize substrates, such as semiconductor wafers. In conventional CMP, a wafer is mounted on a carrier assembly and positioned in contact with a polishing pad in a CMP apparatus. The carrier assembly provides a controllable pressure to the wafer, pressing it against the polishing pad. The pad is moved (e.g., rotated) relative to the wafer by an external driving force. Simultaneously therewith, a polishing composition (“slurry”) or other polishing solution is provided between the wafer and the polishing pad. Thus, the wafer surface is polished and made planar by the chemical and mechanical action of the pad surface and slurry.

There is a great deal of complexity involved in CMP. Each type of material requires a unique polishing composition, a properly designed polishing pad, optimized process settings for both polish and post-CMP clean and other factors that must be individually tailored to the application of polishing a specific material.

A variety of abrasive particles can be used in the polishing or planarization processes. Colloidal silica particles of various sizes are often the abrasive of choice for polishing and planarization of semiconductor wafers. The particles can have various shapes in addition to sizes. Colloidal silica particles having round, elliptical, elongated or nodule shapes are common. Elongated colloidal silica particles are becoming a popular choice for use in alkaline ILD slurry due to their enhanced polishing efficiency compared to silica particles of other shapes.

Certain leading slurries for polishing and planarizing semiconductor wafers include elongated colloidal silica particles, often in combination with colloidal silica particles of other shapes. However, a major problem associated with such slurries is that the slurries can cause pad groove clogging of several types of commercially available polishing pads after extensive polishing periods. Such pad grooves are typically annular in shape. The consequence of the pad groove clogging is substantial removal of polishing uniformity performance. This is exhibited by gradual shifting in polishing uniformity on semiconductor wafer surfaces due to local blockage of slurry transportation during polishing.

FIGS. 1A-C are photographs of the polishing surface (center-to-edge) of a VisionPad™ 5000 polyurethane polishing pad after polishing a semiconductor wafer with an aqueous chemical mechanical polishing slurry composed of water and ˜12 wt % Optiplane™ 1735 abrasive colloidal silica particles. The colloidal silica particles include a mixture of spherical colloidal silica particles with elongated and nodular particles. The pH of the polishing slurry was ˜10.7. The annular grooves had a width of 8 mm, a depth of 2 mm, an outer edge radius of 340 mm and an inner edge radius of 335 mm. Polishing was done on Applied Materials Mirra® polisher with a slurry flow rate: 100 mL/min, a down force of about 34.5 kPa, platen speed 108 rpm and carrier speed of 102 rpm.

FIGS. 1A-C illustrate the degree of clogging of the annular grooves set within the polishing surface of the pad base progressing from near the center of the pad, as shown in FIG. 1A, which shows substantial clogging of the grooves proceeding to a section distal to the center, as shown in FIG. 1B, with slightly reduced clogging of the grooves and then proceeding to the periphery of the pad, as shown in FIG. 1C, with substantially no clogging of the grooves. This is illustrative of the gradual shifting in polishing uniformity. The more clogged the annular grooves the less uniformity is planarization of a semiconductor wafer surface.

Therefore, there is a need for a chemical mechanical polishing slurry and method to inhibit polishing pad groove clogging and simultaneously maintain good polishing and planarization performance.

### SUMMARY OF THE INVENTION

The present invention provides a chemical mechanical polishing composition including water, an abrasive having bimodal distributed colloidal silica particles including elongated colloidal silica particles, polyvinyl alcohol 80% to less than or equal to 90% hydrolyzed, an electrolyte, and a pH greater than 7.

The present invention further provides a chemical mechanical polishing composition including water, an abrasive having bimodal distributed colloidal silica particles including elongated colloidal silica particles, polyvinyl alcohol 80-89% hydrolyzed, an electrolyte, a pH adjusting agent, and a pH of 8 to 12.

The present invention additionally provides a chemical mechanical polishing composition including water, an abrasive having bimodal distributed colloidal silica particles including elongated colloidal silica particles, polyvinyl alcohol 87-89% hydrolyzed, an electrolyte, a pH adjusting agent, and a pH of 9 to 11.

The present invention also provides a method for chemical mechanical polishing a substrate comprising: providing a substrate, wherein the substrate comprises silicon oxide; providing a chemical mechanical polishing composition including water, an abrasive having bimodal distributed colloidal silica particles including elongated colloidal silica particles, polyvinyl alcohol less than 90% hydrolyzed, an electrolyte, and a pH greater than 7; providing a chemical mechanical polishing pad with a polishing surface and grooves; creating dynamic contact at an interface between the polishing surface of the chemical mechanical polishing pad and the substrate with a down force of 20 to 100 kPa; and dispensing the chemical mechanical polishing composition onto the chemical mechanical polishing pad at or near the interface between the chemical mechanical polishing pad and the substrate; and wherein some of the silicon oxide is removed from the substrate.

Surprisingly, the chemical mechanical polishing composition including water, an abrasive having bimodal distributed colloidal silica particles including elongated colloidal silica particles, polyvinyl alcohol 80% hydrolyzed to less than or equal to 90% hydrolyzed, an electrolyte, and a pH greater than 7, and method of polishing a substrate containing silicon dioxide with a polishing pad containing grooves inhibits undesired clogging of the polishing pad grooves during chemical mechanical polishing. Inhibiting clogging of the grooves substantially prevents gradual shifting in polishing uniformity on semiconductor wafer surfaces due to local blockage of slurry transportation, thus enabling improved polishing and planarization performance.

### BRIEF DESCRIPTION OF THE DRAWINGS

FIG. 1A is a photograph taken with a Nikon SMZ 1500 stereo microscope of a section near the center of a polishing surface of a VP5000 polyurethane polishing pad post polishing illustrating annular groove clogging with conventional polishing slurry.

FIG. 1B is a photograph taken with a Nikon SMZ 1500 stereo microscope of a section distal to the center of a polishing surface of an IC1000™ polyurethane polishing pad post polishing illustrating annular groove clogging with conventional polishing slurry.

FIG. 1C is a photograph taken with a Nikon SMZ 1500 stereo microscope of a section on the periphery of a polishing surface of an IC1000™ polyurethane polishing pad post polishing illustrating annular grooves substantially free of polishing slurry.

FIG. 2A is a photograph taken with an iPhone of a polishing surface of a VP5000 polyurethane pad post polishing with a slurry of the present invention illustrating a plurality of annular grooves free of polishing slurry.

FIG. 2B is a photograph taken with a Nikon SMZ 1500 stereo microscope of a section of a polishing surface of a VP5000 polyurethane pad post polishing with a slurry of the present invention illustrating a plurality of annular grooves free of polishing slurry.

### DETAILED DESCRIPTION OF THE INVENTION

As used throughout this specification the following abbreviations have the following meanings, unless the context indicates otherwise: L=liters; mL=milliliters; kPa=kilopascal; Å=angstroms; nm=nanometers; cm=centimeters; mm=millimeters; g=grams; min=minute; rpm=revolutions per minute; wt %=percent by weight; RR=removal rate; PVA=polyvinyl alcohol; PS=Polishing Slurry of the Invention; PC=Comparative Polishing Slurry; Mw=weight average molecular weight g/mole; k=1000; mS=milli-siemens; “˜”=approximately; and VP5000=VisionPad™ 5000 polyurethane polishing pad.

The term “chemical mechanical polishing” or “CMP” refers to a process where a substrate is polished by means of chemical and mechanical forces alone and is distinguished from electrochemical-mechanical polishing (ECMP) where an electric bias is applied to the substrate. The term “TEOS” means the silicon oxide formed from the decomposition of tetraethyl orthosilicate (Si(OC₂H₅)₄). The term “elongated” in reference to colloidal silica abrasive particles means that the abrasive particles have lengths greater than their widths. The term “spherical” in reference to colloidal silica particles means that the abrasive particles are rounded or circular in shape. The term “bimodal distribution” means a set of scores with two (2) peaks or modes around which values tend to cluster, such that the frequencies at first increase and then decrease around each peak and when the peaks are unequal in height, the higher apex or peak is the major mode, and the lower peak is the minor mode (for colloidal silica abrasive particles it may be represented on a Cartesian plane as relative weight of the particles on the Y-axis vs. particle diameter in microns on the X-axis where the X-axis is linear or preferably log). The term “multimodal” means having or involving several modes, modalities, or maxima. The term “monomodal” or “unimodal” means a distribution has only one peak. The term “mean value” refers to the value that falls between the first mode and the second mode (close to the second mode) and is the average value of the entire Cartesian plane graph of relative particle weight vs. particle diameter in microns. The term “dominate”, as used in the present specification, means the mode of a bimodal particle distribution of abrasive colloidal silica particles which has the commanding influence or is the most important mode of the bimodal particle distribution of abrasive colloidal silica particles during chemical mechanical polishing of a substrate. The term “composition” and “slurry” are used interchangeably through-out the specification. The term “halide” means chloride, bromide, fluoride and iodide. The term “electrolyte” means a substance that breaks up into ions (particles with electric charges) when it is dissolved in water. The term “siemens(S) is the international standard (SI) of electrical conductance. The terms “a” and “an” refer to both the singular and the plural. All percentages are by weight, unless otherwise noted. All numerical ranges are inclusive and combinable in any order, except where it is logical that such numerical ranges are constrained to add up to 100%.

The chemical mechanical polishing composition of the present invention includes elongated and spherical colloidal silica abrasive particles having bimodal particle distribution. Preferably, the colloidal silica used contains at least one of precipitated silica and agglomerated silica. Preferably, the bimodal particle distribution of colloidal silica abrasive particles exhibits a first mode with a first average particle size maximum of 50-100 nm, more preferably, from 60-90 nm, further preferably, from 70-90 nm, most preferably from 80-90 nm. Preferably, the elongated colloidal silica abrasive particles exhibit a second mode with a second average particle size maximum of 100-200 nm, more preferably, from 120-180 nm, further preferably, from 130-170 nm, even more preferably, from 140-165 nm, most preferably, from 140-150 nm. The first mode reflects spherical particles while the second mode indicates elongated particles. The second mode dominates the bimodal particle distribution.

Preferably, the mean value of the bimodal particle distribution is from 95-200 nm, more preferably, from 110-180 nm, most preferably from 135-165 nm. Preferably, the mean value falls between the first mode and second mode (close to the second mode).

The chemical mechanical polishing composition of the present invention preferably includes 5-30 wt % colloidal abrasive silica particles of which 50% by weight and greater of the colloidal abrasive silica particles are elongated colloidal abrasive silica particles. More preferably, the chemical mechanical polishing composition of the present invention includes 10-30 wt % colloidal abrasive silica particles of which 50-95% by weight of the colloidal silica abrasive particles are elongated abrasive silica particles, even more preferably, the chemical mechanical polishing composition includes 10-20 wt % colloidal abrasive silica particles of which 70-90% by weight are elongated colloidal silica abrasive particles.

The colloidal silica abrasive particles of the present invention are a mixture of a first population of colloidal silica abrasive particles preferably having an average particle size of 75-80 nm and a second population of colloidal silica abrasive particles preferably having an average particle size of 110-140 nm.

An example of commercially available colloidal silica abrasive which includes bimodal distribution of elongated colloidal silica abrasive particles is Klebosol™ 1635 colloidal silica manufactured by Merck KgAA, Darmstadt, Germany, available from DuPont.

The chemical mechanical polishing composition of the present invention includes polyvinyl alcohol. The polyvinyl alcohol is formed from the hydrolysis of polyvinyl acetate by methods known in the art. Preferably, the degree of hydrolysis of the polyvinyl alcohol is 80% to less than or equal to 90% hydrolyzed, more preferably, the polyvinyl alcohol is 80-89% hydrolyzed, most preferably, from 87-89% hydrolyzed. The degree of hydrolysis refers to the amount of free hydroxyl groups present on the polyvinyl alcohol as compared to the sum of free hydroxyl groups and acetylated hydroxyl groups.

Preferably, the 80% to less than or equal to 90% hydrolyzed polyvinyl alcohol of the present invention has a weight average molecular weight of 9000 g/mole and greater, more preferably, from 10,000-200,000 g/mole, even more preferably, from 10,000-190,000 g/mole, further preferably, from 12,000-150,000 g/mole, most preferably, from 30,000-50,000 g/mole.

Preferably, the polyvinyl alcohol is included in the chemical mechanical polishing compositions of the present invention in amounts of 0.001-0.05 wt %, more preferably, from 0.0025-0.01 wt %, most preferably, from 0.005-0.01 wt %.

One or more electrolytes, inorganic or organic, are included in the chemical mechanical polishing compositions of the present invention to provide a desired conductivity. Preferably, the conductivity of the chemical mechanical polishing compositions of the present invention are from 4 mS/cm and greater, more preferably, from 4-7 mS/cm, most preferably, from 5-7 mS/cm.

Inorganic electrolytes include, but are not limited to alkali metal salts, such as sodium chloride and potassium chloride, ammonium salts, alkali metal hydroxides, such as sodium and potassium hydroxide, alkali metal carbonates, such as sodium and potassium carbonate, alkali metal bicarbonates, such as sodium bicarbonate, phosphate salts, such as potassium phosphate, nitrate salts, such as potassium nitrate, sulfate salts, such as potassium sulfate, and mixtures of the foregoing.

Organic electrolytes include, but are not limited to, choline chloride, carboxylic acids, such as citric acid and acetic acid, quaternary ammonium salts, such as benzyltrimethylammonium chloride, phenyltrimethylammonium chloride, phenyltrimethylammonium bromide and phenyltrimethylammonium hydroxide. Mixtures of the foregoing can be included in the chemical mechanical polishing compositions of the present invention.

Inorganic and organic electrolytes are included in the chemical mechanical polishing compositions in sufficient amounts to obtain the desired conductivity. Preferably, inorganic and organic electrolytes are included in amounts of at least 0.01 wt % and greater, more preferably, from 0.01-1 wt %, further preferably, from 0.05-0.25 wt %.

The chemical mechanical polishing composition used in the chemical mechanical polishing method of the present invention has a pH of >7, preferably, 8-12, more preferably, 9-11.

Optionally, the chemical mechanical polishing composition can include one or more pH adjusting agent to maintain the pH within a desired range. Preferably, the pH adjusting agent is chosen from one or more of sodium hydroxide, potassium hydroxide, ammonium hydroxide, ammonium halide and nitrate salts.

Optionally, the chemical mechanical polishing composition contains biocides, such as KORDEK™ MLX (9.5-9.9% methyl-4-isothiazolin-3-one, 89.1-89.5% water and ≤1.0% related reaction product) or KATHON™ ICP III containing active ingredients of 2-methyl-4-isothiazolin-3-one and 5-chloro-2-methyl-4-isothiazolin-3-one, each manufactured by International Flavors & Fragrances, Inc., (KATHON and KORDEK are trademarks of International Flavors & Fragrances, Inc.).

When biocides are included in the chemical mechanical polishing composition of the present invention, the biocides are included in amounts of 0.0001 wt % to 0.1 wt %, preferably, 0.001 wt % to 0.05 wt %, more preferably. 0.001 wt % to 0.01 wt %, still more preferably, 0.001 wt % to 0.005 wt %.

The water contained in the chemical mechanical polishing composition used in the chemical mechanical polishing method of the present invention is preferably at least one of deionized and distilled to limit incidental impurities.

Preferably, the chemical mechanical polishing composition consists of water, an abrasive of bimodal distributed colloidal silica particles, wherein the colloidal silica particles are elongated and spherical, polyvinyl alcohol 80% to less than or equal to 90% hydrolyzed, an electrolyte, optionally a biocide, optionally a pH adjusting agent and a pH greater than 7.

More preferably, the chemical mechanical polishing composition consists of water, an abrasive of bimodal distributed colloidal silica particles, wherein the colloidal silica particles are elongated and spherical, polyvinyl alcohol 87-89% hydrolyzed, an electrolyte, optionally a biocide, optionally a pH adjusting agent and a pH of 8-12.

Further preferably, the chemical mechanical polishing composition consists of water, an abrasive of bimodal distributed colloidal silica particles, wherein the colloidal silica particles are elongated and spherical, polyvinyl alcohol 87-89% hydrolyzed and having a weight average molecular weight of 9000 g/mole or greater, an electrolyte, optionally a biocide, optionally a pH adjusting agent and a pH of 9-11.

Most preferably, the chemical mechanical polishing composition consists of water an abrasive of bimodal distributed colloidal silica particles, wherein the colloidal silica particles are elongated and spherical, polyvinyl alcohol 87-89% hydrolyzed and having a weight average molecular weight of 12,000-150,000 g/mole, an electrolyte, a conductivity of greater than or equal to 4 mS/cm, optionally a biocide, optionally a pH adjusting agent and a pH of 9-11.

The substrate polished in the chemical mechanical polishing method of the present invention comprises silicon oxide. The silicon oxide in the substrate includes, but is not limited to, borophosphosilicate glass (BPSG), plasma enhanced tetraethyl ortho silicate (PETEOS), silicon oxide formed from the decomposition of tetraethyl orthosilicate (Si(OC₂H₅)₄) known as TEOS, thermal oxide, undoped silicate glass, and high density plasma (HDP) oxide.

The chemical mechanical polishing pad used in the chemical mechanical polishing method of the present invention for silicon oxide removal can by any suitable polishing pad known in the art. The chemical mechanical polishing pad can, optionally, be chosen from woven and non-woven polishing pads. The chemical mechanical polishing pad can be made of any suitable polymer of varying density, hardness, thickness, compressibility, and modulus. The chemical mechanical polishing pad used in the polishing method of the present invention includes grooves on the polishing surface, such as annular grooves. The dimensions of the grooves can vary. All the grooves on a given pad can have the same dimensions or the grooves can vary in dimensions. For example, in one embodiment, annular grooves can have a width of 3-8 mm, a depth of 0.5-2 mm, an outer edge radius of 335-340 mm and an inner edge radius of 330-335 mm. In another embodiment, the grooves can have a width of 3-8 mm, a depth of 0.5-2 mm, an outer edge radius of 35-45 mm and an inner edge radius of 30-40 mm.

Commercially available polishing pads which can be used to practice the method of the present invention include, but are not limited to, VISIONPAD 5000/K7™ polyurethane polishing pad, IC1000™ polyurethane polishing pad and IC1010™ polyurethane polishing pad (available from Rohm and Haas Electronic Materials CMP, LLC).

The chemical mechanical polishing composition used in the chemical mechanical polishing method of the present invention enables operation with a low nominal polishing down force pad pressure, for example, at 20 to 35 kPa on a 300 mm polishing machine with a platen speed of 93-123 revolutions per minute, a carrier speed of 87-117 revolutions per minute, and a chemical mechanical polishing composition flow rate of 40-300 mL/min.

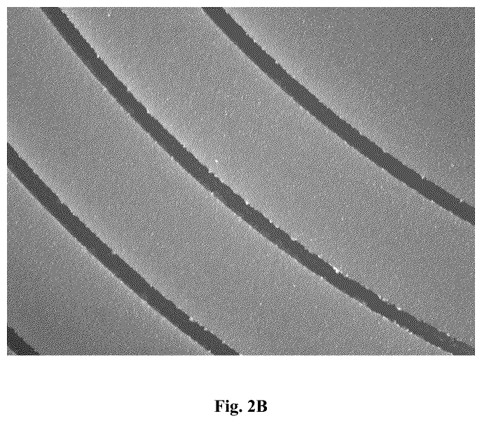

The chemical mechanical polishing composition and method of the present invention inhibits clogging of the grooves of chemical mechanical polishing pads to enable uniform planarization of semiconductor wafers with significant removal rates of TEOS from wafer surfaces. For example, FIGS. 2A-B are photographs of the polishing surface of a VP5000 polyurethane polishing pad after polishing a semiconductor wafer with an aqueous chemical mechanical polishing slurry of the present invention composed of water and 11.5 wt % KLEBOSOL™ 1635 abrasive colloidal silica particles, 0.005 wt % of 89% hydrolyzed polyvinyl alcohol, 0.055 benezyltrimethylammonium chloride, 0.055 wt % choline chloride and 0.164 wt % potassium carbonate and a pH 10.7. The colloidal silica particles included ˜90% elongated colloidal silica particles with the remainder spherical particles.

The annular grooves had a width of 8 mm, a depth of 2 mm, an outer edge radius of 340 mm and an inner edge radius of 335 mm. Polishing was done on Applied Materials Mirra® polisher with a slurry flow rate: 100 mL/min, a down force of about 34.5 kPa, platen speed 108 rpm and carrier speed of 102 rpm.

FIGS. 2A-B illustrate the annular grooves set within the polishing surface of the pad base. FIG. 2A shows a plurality of annular grooves in the polishing surface of the polishing pad base post polishing which shows all the grooves free of polishing slurry. FIG. 2B is a closer image of the polishing pad surface with grooves free of polishing slurry. The chemical mechanical polishing composition and method of the present invention showed unexpected inhibition of polishing pad groove clogging.

The following examples are intended to illustrate the present invention but are not intended to limit its scope.

In the following Examples, unless otherwise indicated, conditions of temperature and pressure are ambient temperature and standard pressure.

The following materials were used in the Examples that follow:

The polishing removal rate experiments were performed on 160 20.3 cm blanket wafers. An Applied Materials Mirra® polisher was used for the Examples. Polishing Examples were performed using an VISIONPAD 5000/K7™ polyurethane polishing pad with grooves 40 mil (1 mm) deep, 18 mil (0.45 mm) grooves and 120 mil (3 mm) pitch (available from Rohm and Haas Electronic Materials CMP, Inc.), with a down force of 31.7 kPa (4.6 psi), a chemical mechanical polishing slurry composition flow rate of 100 mL/min, a table rotation speed of 108 rpm and a carrier rotation speed of 102 rpm. The grooves of the pads were visually observed for cleanliness before and after polishing. The TEOS removal rates were determined by measuring the film thickness before and after polishing using a KLA-Tencor FX200 metrology tool. The polishing slurries were maintained at a pH of around 10.7 during chemical mechanical polishing. Aqueous 2 wt % KOH as added to each slurry to maintain desired pH. Slurry conductivity was measured with a YSI 3200 conductivity meter (available from YSI Incorporated, Yellow Springs, OH 45387 USA). The mean and the mode for the abrasive colloidal silica particles were measured using a CPS Disc Centrifuge™ nano particle size analyzer (available from CPS Instruments, Inc., Stuart, Florida).

### Example 1

### Comparative Chemical Mechanical Polishing Compositions

Aqueous chemical mechanical polishing slurries were prepared as shown in Table 1 below.

TABLE 1

| | | | | | Polyacrylic |
|---|---|---|---|---|---|
| | | | | | Acid (Mw |
| | | Benzyltrimethyl | Choline | Potassium | ~345,000 |
| | Klebosol ™ | Ammonium | Chloride | Carbonate | g/mole) |
| Slurry | 1635 wt % | Chloride wt % | wt % | wt % | wt % |
| PC-1 | 11.5 | 0 | 0 | 0 | 0 |
| PC-2 | 11.5 | 0 | 0.055 | 0 | 0 |
| PC-3 | 11.5 | 0 | 0 | 0.164 | 0 |
| PC-4 | 11.5 | 0.055 | 0.055 | 0 | 0 |
| PC-5 | 11.5 | 0.055 | 0.055 | 0.164 | 0 |
| PC-6 | 11.5 | 0.055 | 0.055 | 0 | 0.125 |

Abrasive: Klebosol™ 1635 bimodal colloidal silica particles containing 50 wt % elongated particles with the remainder spherical, elliptical, or nodular manufactured by Merck KgAA, Darmstadt, Germany, available from DuPont.

TABLE 2

| | Elongated | Elongated | | | Visual |
|---|---|---|---|---|---|
| | Colloidal | Colloidal | | | Observation |
| | Silica | Silica | | TEOS | on Pad after |
| | Mean | Mode (nm) | Conductivity | RR | 160 Wafers |
| Slurry | (nm) | 1^{st}, 2^{nd} | (mS/cm) | (Å/min) | Polished |
| PC-1 | 137 | 83, 141 | 2.9 | 3215 | ~15 grooves |
| | | | | | clogged |
| PC-2 | 137 | 83, 142 | 3.3 | 3083 | ~15 grooves |
| | | | | | clogged |
| PC-3 | 137 | 83, 141 | 5.3 | 3706 | ~20 grooves |
| | | | | | clogged |
| PC-4 | 138 | 83, 143 | 3.7 | 3578 | ~7 grooves |
| | | | | | clogged |
| PC-5 | 139 | 83, 145 | 6.1 | 4096 | ~17 grooves |
| | | | | | clogged |
| PC-6 | 139 | 83, 145 | 4 | 3975 | ~10 grooves |
| | | | | | clogged |

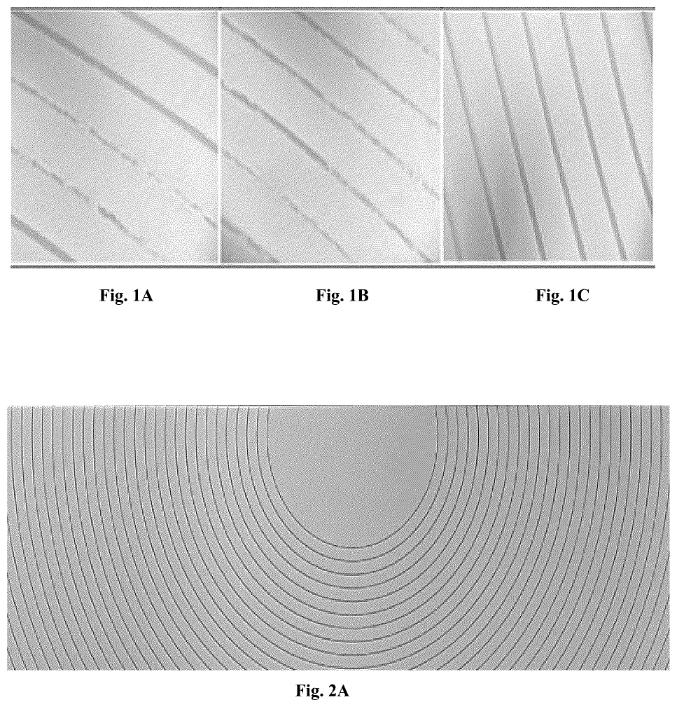

The Klebosol™ 1635 bimodal colloidal silica particles along with the organic and inorganic electrolytes yielded significant VISIONPAD 5000/K7™ polyurethane polishing pad groove clogging. The annular grooves of the polishing pads appeared substantially as in FIGS. 2A-B. In contrast, the annular grooves of the polishing pads of the comparatives appeared 5 substantially as shown in FIGS. 1A-B.

### Example 2

### Chemical Mechanical Polishing Compositions, TEOS RR and Inhibiting Pad Groove Clogging

Aqueous chemical mechanical polishing slurries were prepared as shown in Tables 3A and 3B below. 11.5 wt % Klebosol™ 1635 colloidal silica abrasive was included in each chemical mechanical polishing slurry. The Klebosol™ 1635 colloidal silica abrasive included 50 wt % elongated particles.

TABLE 3A

| | | | | PVA | PVA | PVA |
|---|---|---|---|---|---|---|
| | Benzyltrimethyl | | | (Mw 9K, | (Mw 13- | (Mw 31- |
| | Ammonium | Choline | Potassium | 80% | 23K, 87- | 50K, 87- |
| | Chloride | Chloride | Carbonate | hydrolyzed) | 89% | 89% |
| Slurry | wt % | wt % | wt % | wt % | hydrolyzed) wt % | hydrolyzed) wt % |
| PS-1 | 0.055 | 0.055 | 0.164 | 0 | 0.0025 | 0 |
| PS-2 | 0.055 | 0.055 | 0.164 | 0 | 0.01 | 0 |
| PS-3 | 0.055 | 0.055 | 0.164 | 0 | 0.05 | 0 |
| PS-4 | 0.275 | 0 | 0.21 | 0 | 0.005 | 0 |
| PS-5 | 0.055 | 0.055 | 0.164 | 0.005 | | 0 |
| PS-6 | 0.055 | 0.055 | 0.164 | 0 | 0.005 | 0 |
| PS-7 | 0.055 | 0.055 | 0.164 | 0 | 0 | 0.005 |
| PS-8 | 0.275 | 0 | 0.21 | 0.005 | 0 | 0 |

TABLE 3B

| | | | | PVA | | |
|---|---|---|---|---|---|---|
| | Benzyltrimethyl | | | (Mw 85-124K, | PVA | PVA |
| | Ammonium | Choline | Potassium | 87-89% | (Mw 146-186K, | (Mw 146-186K, |
| | Chloride | Chloride | Carbonate | hydrolyzed) | 87-89% | 99% |
| Slurry | wt % | wt % | wt % | wt % | hydrolyzed) wt % | hydrolyzed) wt % |
| PS-9 | 0.055 | 0.055 | 0.164 | 0.005 | 0 | 0 |
| PS-10 | 0.055 | 0.055 | 0.164 | 0 | 0.005 | 0 |
| PC-7 | 0.055 | 0.055 | 0.164 | 0 | 0 | 0.005 |

TABLE 4

| | Particle | Particle | Con+ | TEOS | |
|---|---|---|---|---|---|
| | Mean | Mode (nm) | ductivity | RR | Grooves |
| Slurry | (nm) | 1^{st}, 2^{nd} | (mS/cm) | (Å/min) | Clogged |
| PS-1 | 137 | 83, 141 | 5.4 | 4188 | ~1 |
| PS-2 | 137 | 84, 142 | 5.5 | 3913 | 0 |
| PS-3 | 138 | 84, 143 | 5.5 | 3522 | 0 |
| PS-4 | 140 | 85, 145 | 6.9 | 3935 | 0 |
| PS-5 | 139 | 83, 145 | 5.7 | 4334 | 0 |
| PS-6 | 139 | 83, 145 | 5.7 | 4056 | 0 |
| PS-7 | 140 | 83, 146 | 5.7 | 4151 | 0 |
| PS-8 | 156 | 87, 161 | 6.8 | 4224 | 0 |
| PS-9 | 141 | 83, 147 | 5.7 | 3874 | 0 |
| PS-10 | 142 | 83, 148 | 5.7 | 3919 | 0 |
| PC-7 | 143 | 83, 149 | 5.7 | 4271 | ~16 |

The polishing results showed that a combination of elongated colloidal silica abrasives with PVA 80-89% hydrolyzed with Mw from 9000-186000 g/mole significantly prevented clogging of the grooves of the VISIONPAD 5000/K7™ polyurethane polishing pad. In addition, TEOS removal rates were just as good, if not better, than the TEOS removal rates of the polishing compositions PC-1-PC-6 of Example 1 above which excluded PVA.

Although PC-7 showed a good TEOS removal rate, ˜16 grooves were clogged. This indicated that PVA 99% hydrolyzed with a Mw from 146000-186000 g/mole was detrimental to inhibiting groove clogging of the VISIONPAD 5000/K7™ polyurethane polishing pad.

### Example 3

### Chemical Mechanical Polishing Compositions, TEOS RR and Inhibiting Pad Groove Clogging with Elongated Vs Spherical Colloidal Silica Particles

Aqueous chemical mechanical polishing slurries were prepared as shown in Table 5 below.

TABLE 5

| | | Klebosol ™ | | | | |
|---|---|---|---|---|---|---|
| | Klebosol ™ | 1635 | Benzyltrimethyl | | | PVA |
| | 1501- | Silica | Ammonium | Choline | Potassium | (Mw 9K, |
| | 50 Silica | Particles | Chloride | Chloride | Carbonate | 80% |
| Slurry | Particles wt % | wt % | wt % | wt % | wt % | hydrolyzed) wt % |
| PC-8 | 30 | 0 | 0 | 0 | 0 | 0 |
| PS-11 | 0 | 11.5 | 0.055 | 0.055 | 0.164 | 0.0075 |
| PS-12 | 0 | 11.5 | 0.055 | 0.055 | 0.164 | 0.01 |

Klebosol™ 1501-50 colloidal silica abrasive included greater than 80 wt % spherical particles with the remainder elongated, elliptical or nodular manufactured by Merck KgAA, Darmstadt, Germany, available from DuPont.

TABLE 6

| | Mean | Mode | Conductivity | TEOS RR | Grooves |
|---|---|---|---|---|---|
| Slurry | (nm) | (nm) | (mS/cm) | (Å/min) | Clogged |
| PC-8 | 77 | 77 | 2.9 | 4601 | ~4 |
| PS-11 | 137 | 83, 142 | 6.3 | 3990 | 0 |
| PS-12 | 137 | 83, 141 | 6.3 | 3645 | 0 |

Although monomodal PC-8 had higher TEOS removal rates than bimodal PS-11 and PS-12 which included electrolytes and 80% hydrolyzed PVA, nevertheless, PS-11 and PS-12 still showed high TEOS removal rates. More importantly. PC-8 had some undesired groove clogging whereas PS-11 and PS-12 showed none.

What is claimed is:

1. A chemical mechanical polishing composition comprising water, an abrasive having bimodal distributed colloidal silica particles including elongated colloidal silica particles, polyvinyl alcohol 80% to less than or equal to 90% hydrolyzed, an electrolyte, and a pH greater than 7.

2. The chemical mechanical polishing composition of claim 1, wherein the polyvinyl alcohol is 80-89% hydrolyzed.

3. The chemical mechanical polishing composition of claim 2, wherein the polyvinyl alcohol is 87-89% hydrolyzed.

4. The chemical mechanical polishing compositions of claim 1, wherein a weight average molecular weight of the polyvinyl alcohol 80% to less than or equal to 90% hydrolyzed is 9000 g/mole or greater.

5. The chemical mechanical polishing composition of claim 4, wherein the weight average molecular weight is 12,000-150,000 g/mole.

6. The chemical mechanical polishing composition of claim 1, wherein the amount of polyvinyl alcohol 80% to less than or equal to 90% hydrolyzed is from 0.001-0.01 wt %.

7. The chemical mechanical polishing composition of claim 1, wherein the chemical mechanical polishing composition has a conductivity of 4 mS/cm and greater.

8. The chemical mechanical polishing composition of claim 1, wherein the pH is 8-12.

9. The chemical mechanical polishing composition of claim 1, wherein the bimodal distributed elongated colloidal silica particles have a first mode with a first particle size maximum of 50-100 nm and a second mode with a second particle size maximum of 100-200 nm.

10. A method for chemical mechanical polishing a substrate comprising: providing a substrate, wherein the substrate comprises silicon oxide; providing a chemical mechanical polishing composition composed of water, an abrasive having bimodal distributed colloidal silica particles including elongated colloidal silica particles, polyvinyl alcohol 80% to less than 90% hydrolyzed, an electrolyte, optionally a biocide, optionally a surfactant, optionally, a pH adjusting agent, and a pH greater than 7; and
providing a chemical mechanical polishing pad with a polishing surface and grooves; creating dynamic contact at an interface between the polishing surface of the chemical mechanical polishing pad and the substrate with a down force of 20 to 35 kPa; and dispensing the chemical mechanical polishing composition onto the chemical mechanical polishing pad at or near the interface between the chemical mechanical polishing pad and the substrate; and
wherein some of the silicon oxide is removed from the substrate.
